(19) United States
(12) Patent Application Publication
(10) Pub. No.: US 2009/0211633 A1
(43) Pub. Date: Aug. 27, 2009

(54) Tandem Photovoltaic Cells

(75) Inventors: Pavel Schilinsky, Nuremberg (DE); Stelios A. Choulis, Piraeus (GR)

Correspondence Address: FISH & RICHARDSON PC, P.O. BOX 1022, MINNEAPOLIS, MN, 55440-1022, US

(73) Assignee: Konarka Technologies Inc., Lowell, MA (US)

(21) Appl. No.: 12/389,041

(22) Filed: Feb. 19, 2009

Related U.S. Application Data
(60) Provisional application No. 61/030,353, filed on Feb. 21, 2008.

(51) Int. Cl. H01L 31/00

(52) U.S. Cl. 136/256

(57) ABSTRACT

Tandem photovoltaic cells, as well as related systems, methods, and components, are disclosed.

### CROSS REFERENCE TO RELATED APPLICATIONS

Pursuant to 35 U.S.C. §119(e), this application claims priority to U.S. Provisional Application Ser. No. 61/030,353, filed Feb. 21, 2008, the contents of which are hereby incorporated by reference.

### TECHNICAL FIELD

This disclosure relates to tandem photovoltaic cells, as well as related systems, methods, and components.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material to generate electricity. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because, although the semiconductive material may have a lower electrical conductivity than electrically conductive materials, the semiconductive material can transmit more light than many electrically conductive materials.

There is an increasing interest in the development of photovoltaic technology due primarily to a desire to reduce consumption of and dependency on fossil fuel-based energy sources. Photovoltaic technology is also viewed by many as being an environmentally friendly energy technology. However, for photovoltaic technology to be a commercially feasible energy technology, the material and manufacturing costs of a photovoltaic system (a system that uses one or more photovoltaic cells to convert light to electrical energy) should be recoverable over some reasonable time frame. But, in some instances the costs (e.g., due to materials and/or manufacture) associated with practically designed photovoltaic systems have restricted their availability and use.

### SUMMARY

This disclosure relates to tandem photovoltaic cells, as well as related systems, methods, and components.

In one aspect, this disclosure features systems that include first and second semi-cells. The first semi-cell includes a first electrode, a third electrode, and a first photoactive layer between the first and third electrodes. The second semi-cell includes a second electrode, the third electrode, and a second photoactive layer between the second and third electrodes. The first and second semi-cells are electrically connected in parallel. The third electrode is between the first and second electrodes and includes a first material selected from the group consisting of metals, carbon nanotubes, carbon nanorods, fallerenes, and combinations thereof. The systems are configured as photovoltaic systems.

In another aspect, this disclosure features systems that include first and second electrodes, a third electrode between the first and second electrodes, a first photoactive layer between the first and third electrodes, and a second photoactive layer between the second and third electrodes. The first and second electrodes have the same polarity during use of the systems. The third electrode has a polarity opposite to the polarity of the first and second electrodes during use of the systems. The third electrode includes first and second materials, the first material being selected from the group consisting of metals, carbon nanotubes, carbon nanorods, fullerenes, and combinations thereof and the second material being selected from the group consisting of metal oxides, electrically conductive polymers, and combinations thereof. The systems are configured as photovoltaic systems.

In another aspect, this disclosure features methods that include disposing a third electrode between first and second photoactive layers to form an intermediate article, and disposing the intermediate article between first and second electrodes to form first and second semi-cells. The first and second semi-cells are electrically connected in parallel. The first semi-cell includes the first electrode, the third electrode, and the first photoactive layer. The second semi-cell includes the second electrode, the third electrode, and the second photoactive layer. The third electrode is disposed via a liquid-based coating process.

In another aspect, this disclosure features methods that include forming a third electrode supported by a first photoactive layer to provide an intermediate article, and forming additional components to the intermediate article to provide a photovoltaic system. The third electrode is formed from a liquid-based coating composition. The photovoltaic system includes a first semi-cell that is electrically connected to a second semi-cell. The first semi-cell includes a first electrode, a third electrode, and the first photoactive layer between the first and third electrodes. The second semi-cell includes a second electrode, the third electrode, and a second photoactive layer between the second and third electrodes. The third electrode is between the first and second electrodes.

In another aspect, this disclosure features methods that include disposing a liquid-based coating composition so that the composition is supported by a first photoactive layer, and forming the composition into a first electrode that includes first and second materials, the first material being selected from the group consisting of metals, carbon nanotubes, carbon nanorods, fullerenes, and combinations thereof and the second material being selected from the group consisting of metal oxides, electrically conductive polymers, and combinations thereof, thereby providing an intermediate article containing the first photoactive layer and the first electrode. In some embodiments, the methods further include disposing the intermediate article on a second electrode to form a first semi-cell that includes the first and second electrodes, and the first photoactive layer between the first and second electrodes. In some embodiments, the methods further include disposing a second photoactive layer on the first electrode, and disposing a third electrode on the second photoactive layer to form a second semi-cell that includes the first and third electrodes, and the second photoactive layer between the first and third electrodes. The first and second semi-cells are electrically connected.

In another aspect, this disclosure features systems that include a tandem photovoltaic cell. The tandem photovoltaic cell includes two semi-cells and a shared electrode between the two semi-cells. The shared electrode includes first and second materials, the first material selected from the group consisting of metals, carbon nanotubes, carbon nanorods, fullerenes, and combinations thereof and the second material being selected from the group consisting of metal oxides, electrically conductive polymers, and combinations thereof.

In another aspect, this disclosure features systems that include first, second, and third electrodes, first and second photoactive layers, and first and second hole carrier layers. The third electrode is between the first and second electrodes. The first photoactive layer is between the first and third electrodes, and the second photoactive layer is between the second and third electrodes. The first hole carrier layer is between the first photoactive layer and the third electrode, and the second hole carrier layer is between the second photoactive layer and third electrode. The systems are configured as a photovoltaic system. In some embodiments, the systems further include first and second hole blocking layers, the first hole blocking being between the first photoactive layer and the first electrode and the second hole blocking layer being between the second photoactive layer and second electrode.

In still another aspect, this disclosure features systems that include first, second, and third electrodes, first and second photoactive layers, and first and second hole carrier layers. The third electrode is between the first and second electrodes. The first photoactive layer is between the first and third electrodes, and the second photoactive layer is between the second and third electrodes. The first hole carrier layer is between the first photoactive layer and the first electrode, and the second hole carrier layer is between the second photoactive layer and second electrode. The systems are configured as a photovoltaic system. In some embodiments, the systems further include first and second hole blocking layers, the first hole blocking being between the first photoactive layer and the third electrode and the second hole blocking layer being between the second photoactive layer and third electrode.

Embodiments can include one or more of the following features.

In some embodiments, the first and second semi-cells are electrically connected in parallel. In certain embodiments, the first and second semi-cells are electrically connected in series.

In some embodiments, the third electrode further includes a second material. The second material can include a metal oxide, an electrically conductive polymer, or a combination thereof. In some embodiments, the metal oxide can be selected from the group consisting of zinc oxides, titanium oxides, indium tin oxides, and tin oxides. In certain embodiments, the metal oxide is in the form of nanoparticles. In some embodiments, the electrically conductive polymer can be selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers thereof.

In some embodiments, the first material in the common electrode between first and second semi-cells includes a metal selected from the group consisting of iron, gold, silver, copper, aluminum, nickel, palladium, platinum, titanium, and alloys thereof. In certain embodiments, the first material includes metal nanoparticles or metal nanorods. In certain embodiments, the first material includes a metal mesh or a metal grid.

In some embodiments, the third electrode includes a first electrode layer and a second electrode layer. In some embodiments, the first electrode layer includes a first species of the second material and the second electrode layer includes a second species of the second material. In certain embodiments, the first species is different from the second species. In some embodiments, the first and second species each includes an n-type semiconductor material or each includes a p-type semiconductor material.

In some embodiments, the third electrode further includes an electrically conductive layer between the first and second electrode layers. In certain embodiments, the electrically conductive layer includes the first material.

In some embodiments, the system further includes a first hole carrier layer between the first photoactive layer and the first electrode, and a second hole carrier layer between the second photoactive layer and the second electrode. In certain embodiments, the system further includes a first hole blocking layer between the first photoactive layer and the third electrode, and a second hole blocking layer between the second photoactive layer and the third electrode.

In some embodiments, the system further includes a first hole blocking layer between the first photoactive layer and the first electrode, and a second hole blocking layer between the second photoactive layer and the second electrode. In certain embodiments, the system further includes a first hole carrier layer between the first photoactive layer and the third electrode, and a second hole carrier layer between the second photoactive layer and the third electrode.

In some embodiments, the third electrode has a thickness of at least about 10 nm and/or at most about 1 micron.

In some embodiments, the third electrode has a surface resistance of at most about 500 ohm/square (e.g., at most about 10 ohm/square).

In some embodiments, the third electrode has a transmittance of at least about 60% (e.g., at least about 80%).

In some embodiments, the photovoltaic system includes a tandem photovoltaic cell.

In some embodiments, the liquid-based coating process includes solution coating, ink jet printing, spin coating, dip coating, knife coating, bar coating, spray coating, roller coating, slot coating, gravure coating, flexographic printing, or screen printing.

In some embodiments, the third electrode is prepared from a liquid-based coating composition.

In some embodiments, the liquid-based coating composition includes a semiconductor material or a precursor thereof. In some embodiments, the semiconductor material includes a metal oxide or a precursor thereof, or an electrically conductive polymer. In certain embodiments, the liquid-based coating composition further includes a material selected from the group consisting of metals, carbon nanotubes, carbon nanorods, fullerenes, and combinations thereof.

In some embodiments, the liquid-based coating composition includes a sol-gel composition.

Embodiments can provide one or more of the following advantages.

In some embodiments, the common electrode between two semi-cells can be prepared by a liquid-based coating process, which can result in an electrode with a large thickness (e.g., 30-1,000 nm). Such an electrode can protect the layers underneath the third electrode from further processes during the manufacture of a photovoltaic cell. The large thickness of the common electrode can also reduce the numbers of pinholes within the electrode and thus enhance its conductivity. In some embodiments, the common electrode layer with a large thickness can be pinhole free.

In some embodiments, the common electrode prepared by a liquid-based coating process has a smaller density than an electrode prepared by a conventional process, such as sputtering. The common electrode with a smaller density can have a better light transmission through the electrode.

In some embodiments, the common electrode includes one or more materials selected from the group consisting of metals, carbon nanotubes, carbon nanorods, fullerenes, electrically conductive polymers, and combinations thereof. Such materials can significantly enhance the conductivity of the electrode and allow the electrode to be used as a common electrode in a parallel connected tandem photovoltaic cell, in which the common electrode desirably has a sufficiently high conductivity to conduct current.

In some embodiments, the two semi-cells in the tandem photovoltaic cell are electrically connected in parallel. The parallel connection of the semi-cells can greatly reduce the losses caused by the interconnection of the two cells and enhance the efficiency of the tandem photovoltaic cell.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of an embodiment of a parallel tandem photovoltaic cell.

FIG. 2 is a cross-sectional view of another embodiment of a parallel tandem photovoltaic cell.

FIG. 3 is a cross-sectional view of a embodiment of a series tandem photovoltaic cell.

FIG. 4 is a schematic of a system containing multiple photovoltaic cells electrically connected in series.

FIG. 5 is a schematic of a system containing multiple photovoltaic cells electrically connected in parallel.

Like reference symbols in the various drawings indicate like elements.

### DETAILED DESCRIPTION

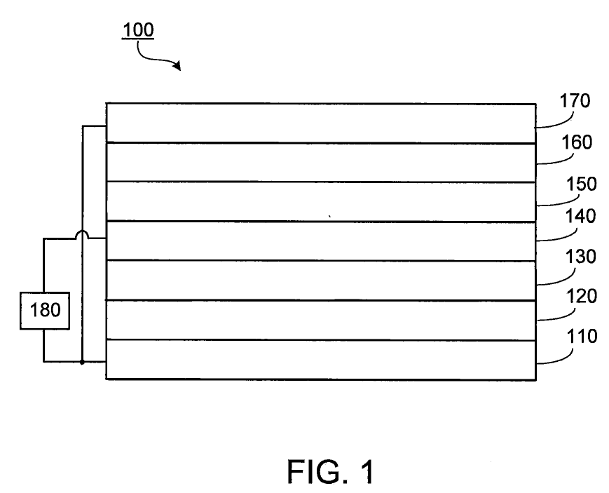

FIG. 1 shows a parallel tandem photovoltaic cell 100 having an electrode 110, a photovoltaic layer 120, a hole carrier layer 130, an electrode 140, a hole carrier layer 150, a photovoltaic layer 160, an electrode 170, an electrical connection between electrodes 110 and 170, and an external load 180 electrically connected to photovoltaic cell 100 via electrodes 110, 140, and 170.

Photovoltaic cell 100 includes two semi-cells. The first semi-cell includes electrode 110, photovoltaic layer 120, hole carrier layer 130, and electrode 140. The second semi-cell includes electrode 140, hole carrier layer 150, photovoltaic layer 160, and electrode 170. The first and second semi-cells have electrically connected electrodes 110 and 170 and share a common electrode 140 such that they are electrically connected in parallel.

In general, during use, light can impinge on the surface of electrode 110 of the first semi-cell, and pass through electrode 110. The light then interacts with photoactive layer 120. The residual light further passes through hole carrier layer 130, electrode 140, and hole carrier layer 150, and interacts with photoactive layer 160 of the second semi-cell. The interactions between the light and photoactive layers 120 and 160 cause the electrons to be transferred from an electron donor material (e.g., poly(3-hexylthiophene) (P3HT)) to an electron acceptor material (e.g., C61-phenyl-butyric acid methyl ester (C61-PCBM)) within each photoactive layer. The electron acceptor material in each photoactive layer then transfers the electrons to electrode 110 or 170. The electron donor material in layer 120 transfers holes through hole carrier layer 130 to electrode 140 and the electron donor material in layer 160 transfers holes though hole carrier layer 150 to electrode 140. During use, electrodes 110 and 170 (having the same polarity) are electrically connected to electrode 140 (having a polarity opposite to that of electrodes 110 and 170) via external load 180 so that electrons pass from electrodes 110 and 170, through external load 180, and to electrode 140.

Without wishing to be bound by theory, it is believed that an advantage of photovoltaic cell 100 is that the current generated by each semi-cell is proportional to the incident light absorption of each semi-cell, while the voltage over each semi-cell is substantially independent from the incident light absorption. For example, the voltage of photovoltaic cell 100 does not change, or changes by a very small percentage (e.g., at most about 5% or at most about 10%) when the incident light absorption changes within a range of about 0-50%. In embodiments where incident light enters photovoltaic cell 100 through electrode 110, the first semi-cell can absorb a majority of the incident light, while the second semi-cell only absorbs the residual incident light. As such, the first semi-cell can generate a larger current than the second semi-cell. In such embodiments, the voltages generated by each semi-cell in photovoltaic cell 100 can still be substantially the same.

Since the first and second semi-cells are electrically connected in parallel, the current output of photovoltaic cell 100 is the sum of the currents generated in the two semi-cell. Such a current output is significantly higher than the current output of photovoltaic cells in which two semi-cells are electrically connected in series, which is limited by the lowest current generated by a semi-cell. In general, in series connected tandem photovoltaic cells, each semi-cell preferably generates a similar amount of current to achieve the maximum efficiency. However, without wishing to be bound by theory, it is believed that one advantage of photovoltaic cell 100 is that it does not require each semi-cell to generate a similar amount of current. Further, because of the voltage generated by each of the two semi-cells in photovoltaic cell 100 is substantially identical, the losses caused by the interconnection of the semi-cells are minimized.

In some embodiments, electrode 140 is formed of one or more electrically conductive materials. Examples of electrically conductive materials include electrically conductive inorganic materials (such as metals, alloys, and metal oxides) and electrically conductive organic materials (such as polymers, fullerenes, carbon nanotubes, and carbon nanorods). Exemplary electrical conductive metals include iron, gold, silver, copper, aluminum, nickel, palladium, platinum, and titanium. Exemplary electrical conductive alloys include stainless steel (e.g., 332 stainless steel, 316 stainless steel), alloys of gold, alloys of silver, alloys of copper, alloys of aluminum, alloys of nickel, alloys of palladium, alloys of platinum, and alloys of titanium. Exemplary electrically conductive metal oxides include zinc oxides, titanium oxides, tin oxides, indium tin oxides (ITO), and tin oxides. In some embodiments, the electrically conductive metal oxides include one or more suitable dopants, such as Al, Cr, Mg, Nb, F, C, and N. In some embodiments, a doped metal oxide is a non-stoichiometric metal oxide, in which the dopant is oxygen vacancy. Exemplary electrically conductive polymers include polythiophenes, polyanilines, polycarbazoles, polyvinylcarbazoles, polyphenylenes, polyphenylvinylenes, polysilanes, polythienylenevinylenes, polyisothianaphthanenes, or copolymers thereof. In some embodiments, the electrically conductive polymers include doped polymers, such as doped polyanilines or doped poly(3,4-ethylene dioxythiophene)s (doped PEDOTs). Without wishing to be bound by theory, it is believed that a higher dopant concentration in an electrically conductive metal oxide or polymer can increase the conductivity of the metal oxide or polymer. In some embodiments, combinations of electrically conductive materials are used.

In some embodiments, the material included in electrode 140 is in the form of nanoparticles (e.g., metal nanoparticles or metal oxide nanoparticles), nanotubes (e.g., carbon nanotubes), or nanorods (e.g., metal nanorods or carbon nanorods). Without wishing to be bound by theory, it is believed that a material in the form of nanoparticles, nanotubes, or nanorods can facilitate light transmission through the electrode.

In some embodiment, electrode 140 includes a first material and a second material. The first material can be selected from the group consisting of metals, carbon nanotubes, carbon nanorods, fullerenes, and combinations thereof. The second material can be selected from metal oxides, electrically conductive polymers, and combinations thereof. Without wishing to be bound by theory, it is believed that electrode 140 in a parallel connected tandem photovoltaic cell has both high transparency to allow incident light to reach both photoactive layers 120 and 160 and high conductivity to allow current generated by the tandem cell to flow through electrode 140 with minimum loss. In some embodiments, without wishing to be bound by theory, it is believed that the second material can be a transparent material without a very high conductivity and the first material can be a highly conductive material that can compensate the conductivity of the second material. By contrast, a common electrode in a series connected tandem photovoltaic cell does not conduct current and therefore does not need to be conductive. Such a common electrode is generally very thin (e.g., less than 10 nm) to provide a sufficient transparency and has a very low conductivity due to its small thickness.

In some embodiments, electrode 140 includes ITO nanoparticles together with an additional electrically conductive material (e.g., metal nanoparticles, carbon nanotubes, and/or carbon nanorods). Generally, to be used effectively in a parallel connected tandem photovoltaic cell, an electrode made of ITO typically has a suitable thickness (e.g., 10 nm to 1 μm) to allow sufficient light to be transmitted through the electrode and to provide sufficient conductivity. At such a thickness, the surface resistance of the ITO is typically much higher than the ideal surface resistance of an electrode (e.g., less than about 10 Ohm/sq). Combining ITO with an additional electrically conductive material in electrode 140 can significantly enhance the conductivity of electrode 140, while maintaining its relatively high transparency.

In some embodiments, electrode 140 includes a layer of metal grid or metal mesh and a layer of an additional electrically conductive material (e.g., metal nanoparticles, carbon nanotubes, and/or carbon nanorods). The additional electrically conductive material can significantly enhance the conductivity of electrode 140, while maintaining its relatively high transparency. Examples of grid or mesh electrodes have been described in, for example, commonly-owned co-pending U.S. Patent Application Publication Nos. 20040187911, 20060090791, 20070131277, and 20070193621, the contents of which are hereby incorporated by reference. In some embodiments, a metal mesh layer (e.g., a metal layer with small openings in the layer) can be prepared from a metal print paste (e.g., silver print paste). Such a mesh layer typically includes a continuous layer of metal particles, which have space between them and are supported by a filler material (e.g., a polymer). In some embodiments, the metal grid or metal mesh is at least partially embedded in the additional electrically conductive material. In such embodiments, the additional electrically conductive material can at least partially fill in the space between the metal grid or metal mesh.

In some embodiments, electrode 140 includes at least about 40 wt % (e.g., at least about 50 wt % or at least about 60 wt %) and/or at most about 95 wt % (e.g., at most about 90 wt % or at most about 85 wt %) of the additional electrically conductive material.

In some embodiments, electrode 140 is substantially transparent. As used herein, a transparent material refers to a material that, at the thickness used in a tandem photovoltaic cell 100, can transmit at least about 60% (e.g., at least about 70%, at least about 80%, at least about 90%, or at least about 95%) of the incident light at a wavelength or a range of wavelengths (e.g., from about 350 nm to about 1,000 nm) used during the operation of the photovoltaic cell.

Generally, electrode 140 has a sufficiently low surface resistance. In some embodiments, electrode 140 has a surface resistance of at most about 500 Ohm/sq (e.g., at most about 100 Ohm/sq, at most about 30 Ohm/sq, or at most about 10 Ohm/sq).

Electrode 140 generally has a sufficient thickness to provide high conductivity to facilitate conducting current and to protect the layers underneath from any solvent applied onto electrode 140. In some embodiments, electrode 140 has a thickness of at least about 10 nm (e.g., at least about 30 nm, at least about 50 nm, or at least about 100 nm) and/or at most about 1,000 nm (e.g., at most about 800 nm or at most about 500 nm). In general, electrode 140 has a larger thickness than a common electrode in a series connected tandem photovoltaic cell because such a common electrode does not conduct current and therefore does not need to be thick to provide high conductivity.

In some embodiments, electrode 140 is prepared by a liquid-based coating process. The term “liquid-based coating process” mentioned herein refers to a process that uses a liquid-based coating composition. Examples of the liquid-based coating composition include a solution, a dispersion, or a suspension. The concentration of a liquid-based coating composition can generally be adjusted as desired. In some embodiments, the concentration can be adjusted to achieve a desired viscosity of the coating composition or a desired thickness of the coating.

The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Without wishing to bound by theory, it is believed that the liquid-based coating process can be readily used in a continuous manufacturing process, such as a roll-to-roll process, thereby significantly reducing the cost of preparing a photovoltaic cell. Examples of roll-to-roll processes have been described in, for example, commonly-owned co-pending U.S. Application Publication No. 2005-0263179, the contents of which are hereby incorporated by reference.

In some embodiments, when electrode 140 includes a layer containing an inorganic semiconductor nanoparticles (e.g., titanium oxide nanoparticles) and metal nanoparticles (e.g., silver nanoparticles or copper nanoparticles), the liquid-based coating process can be carried out by (1) dispersing a precursor (e.g., a titanium salt) of the inorganic semiconductor nanoparticles and metal nanoparticles in a suitable solvent (e.g., an anhydrous alcohol) to form a dispersion, (2) coating the dispersion on hole carrier layer 130, (3) hydrolyzing the dispersion, and (4) drying the dispersion to form an electrode. In certain embodiments, the liquid-based coating process can be carried out by a sol-gel process.

In some embodiments, when electrode 140 includes a layer of metal grid or metal mesh and a layer of an additional electrically conductive material (e.g., metal nanoparticles, carbon nanotubes, and/or carbon nanorods), it can be prepared by first applying the layer of the additional electrically conductive material onto hole carrier layer 130 by a liquid-based coating process (such as the processes described above) and then applying the layer of metal grid or mesh onto the layer just formed. Exemplary methods of forming mesh or grid electrodes have been described in, for example, U.S. Patent Application Publication Nos. 20040187911 and 20070193621.

In some embodiments, electrode 140 prepared by a liquid-based coating process has a larger thickness than that prepared by a non liquid-based coating process (e.g., sputtering). For example, the typical thickness of an ITO electrode prepared by sputtering is less than about 30 nm, while electrode 140 prepared by a liquid-based coating process can have a thickness larger than 30 nm and up to 1,000 nm. Without wishing to be bound by theory, it is believed that electrode 140 with a larger thickness can provide high conductivity and protect the layers underneath from further coating processes applied on electrode 140 during the manufacturing of tandem photovoltaic cell 100. In addition, electrode 140 with a large thickness has a reduced number of pinholes. In some embodiments, electrode 140 with a large thickness can be pinhole free. Without wishing to be bound by theory, it is believed that pinholes in an electrode can introduce a large resistance and greatly reduce the conductivity of the electrode. Thus, without wishing to be bound by theory, it is believed that a pin-hole free electrode can have a high conductivity and therefore can enhance the performance of the photovoltaic cell.

Generally, an electrode prepared by a liquid-based coating process has a lower density than that prepared by a non liquid-based coating process (e.g., sputtering). Without wishing to be bound by theory, it is believed that a layer having a lower density can provide a better light transparency, but possesses a lower conductivity. Unexpectedly, electrode 140 prepared by a liquid-coating process has a sufficiently high conductivity that is comparable to a conventional electrode prepared by sputtering. For example, the surface resistance of electrode 140 can be less than about 10 Ohm/sq.

In some embodiments, electrode 140 includes multiple layers (e.g., two, three, or more layers). In certain embodiments, electrode 140 includes first and second layers, where the first layer serves as an electrode of the first semi-cell and the second layer serve as an electrode of the second semi-cell. Both layers can be made of the electrically conductive materials discussed above. Generally, the first layer can be made of a material the same as or different from the material used in the second layer. In some embodiments, each layer can include an n-type semiconductor material or a p-type semiconductor material. In some embodiments, at least a portion of hole carrier layers 130 and 150 can be at least a portion of the first and second layers of electrode 140, respectively.

In certain embodiments, electrode 140 has three layers, in which the first layer serves as an electrode of the first semi-cell, the second layer serves as an electrode of the second semi-cell, and the third layer is between the first and second layers. Each of the first, second, and third layers can be made of the same or different materials and can be made from the electrically conductive materials discussed above. In some embodiments, the third layer can be made of a material that has higher conductivity than the first and second layers and can enhance the conductivity of electrode 140 when the conductivity of the first and second layers is not sufficient. In some embodiments, at least a portion of hole carrier layers 130 and 150 can be at least a portion of the first and second layers of electrode 140, respectively. In general, electrode 140 with multiple layers can also be prepared by a liquid-based coating process.

Turning to other components of photovoltaic cell 100, electrodes 110 and 170 are generally formed of an electrically conductive material, such as one of the electrically conductive materials discussed above. They can have the same characteristics (e.g., thickness, transmittance, or surface resistance) as electrode 140. In some embodiments, certain characteristics of electrodes 110 and 170 are the same as the corresponding characteristics of electrode 140 and certain characteristics of electrodes 110 and 170 are different from those of electrode 140. In general, electrodes 110 and 170 can also be prepared by a liquid-based coating process discussed above. Examples of materials and methods that can be used to prepare an electrode in a photovoltaic cell have been described in, for example, commonly-owned co-pending U.S. Patent Application Publication Nos. 20040187911, 20060090791, 20070131277, and 20070193621.

Each of photoactive layers 120 and 160 generally contains an electron acceptor material (e.g., an organic electron acceptor material) and an electron donor material (e.g., an organic electron donor material).

Examples of electron acceptor materials include fallerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, a combination of electron acceptor materials can be used in photoactive layer 120 or 160.

In some embodiments, the electron acceptor material includes a fullerene, such as a substituted fullerene (e.g., C61-PCBM or C71-PCBM). In certain embodiments, a fullerene has 50-250 carbon atoms in its carbon skeleton.

In some embodiments, the electron donor materials include conjugated polymers, such as polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polytetrahydroisoindoles, and copolymers thereof. In some embodiments, the electron donor material can be polythiophenes (e.g., poly(3-hexylthiophene)), polycyclopentadithiophenes, and copolymers thereof. In certain embodiments, a combination of electron donor materials can be used in photoactive layer 120 or 160.

In some embodiments, the electron donor materials or the electron acceptor materials can include a polymer having a first comonomer repeat unit and a second comonomer repeat unit different from the first comonomer repeat unit. The first comonomer repeat unit can include a cyclopentadithiophene moiety, a silacyclopentadithiophene moiety, a cyclopentadithiazole moiety, a thiazolothiazole moiety, a thiazole moiety, a benzothiadiazole moiety, a thiophene oxide moiety, a cyclopentadithiophene oxide moiety, a polythiadiazoloquinoxaline moiety, a benzoisothiazole moiety, a benzothiazole moiety, a thienothiophene moiety, a thienothiophene oxide moiety, a dithienothiophene moiety, a dithienothiophene oxide moiety, or a tetrahydroisoindoles moiety.

In some embodiments, the first comonomer repeat unit includes a cyclopentadithiophene moiety. In some embodiments, the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, and SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, the cyclopentadithiophene moiety can be substituted with hexyl, 2-ethylhexyl, or 3,7-dimethyloctyl. In certain embodiments, the cyclopentadithiophene moiety is substituted at 4-position. In some embodiments, the first comonomer repeat unit can include a cyclopentadithiophene moiety of formula (1):

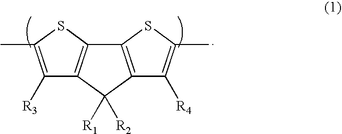

In formula (1), each of H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be hexyl, 2-ethylhexyl, or 3,7-dimethyloctyl.

An alkyl can be saturated or unsaturated and branch or straight chained. A C₁-C₂₀ alkyl contains 1 to 20 carbon atoms (e.g., one, two, three, four, five, six, seven, eight, nine, 10, 11, 12, 13, 14, 15, 16, 17, 18, 19, and 20 carbon atoms). Examples of alkyl moieties include —CH₃, —CH₂—, —CH₂═CH₂—, —CH₂—CH═CH₂, and branched —C₃H₇. An alkoxy can be branch or straight chained and saturated or unsaturated. An C₁-C₂₀ alkoxy contains an oxygen radical and 1 to 20 carbon atoms (e.g., one, two, three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieities include cyclohexyl and cyclohexen-3-yl. A heterocycloalkyl can also be either saturated or unsaturated. A C₃-C₂₀ heterocycloalkyl contains at least one ring heteroatom (e.g., O, N, and S) and 3 to 20 carbon atoms (e.g., three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, cyano, nitro, acyl, acyloxy, carboxyl, and carboxylic ester. Examples of sub stituents on alkyl include all of the above-recited substituents except C₁-C₂₀ alkyl. Cycloalkyl, heterocycloalkyl, aryl, and heteroaryl also include fused groups.

The second comonomer repeat unit can include a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety. In some embodiments, the second comonomer repeat unit is a 3,4-benzo-1,2,5-thiadiazole moiety.

In some embodiments, the second comonomer repeat unit can include a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34):

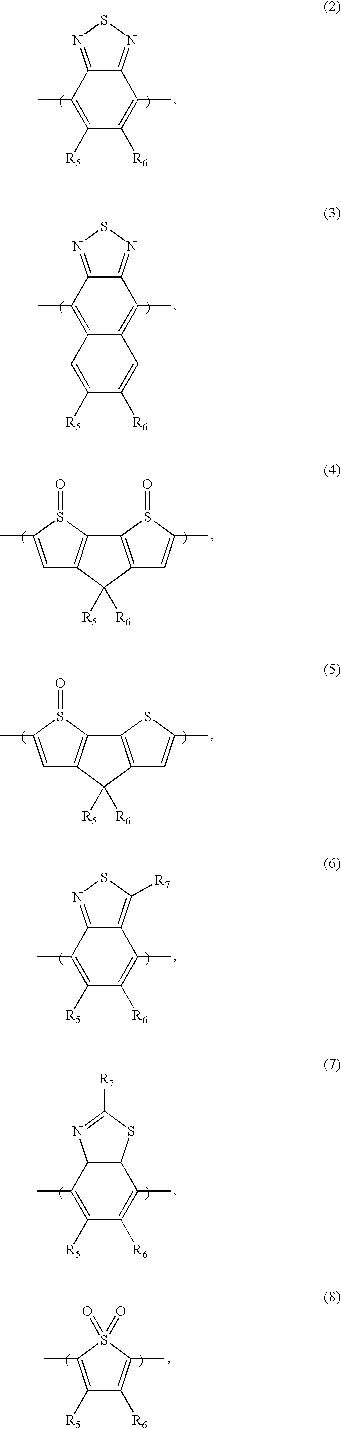

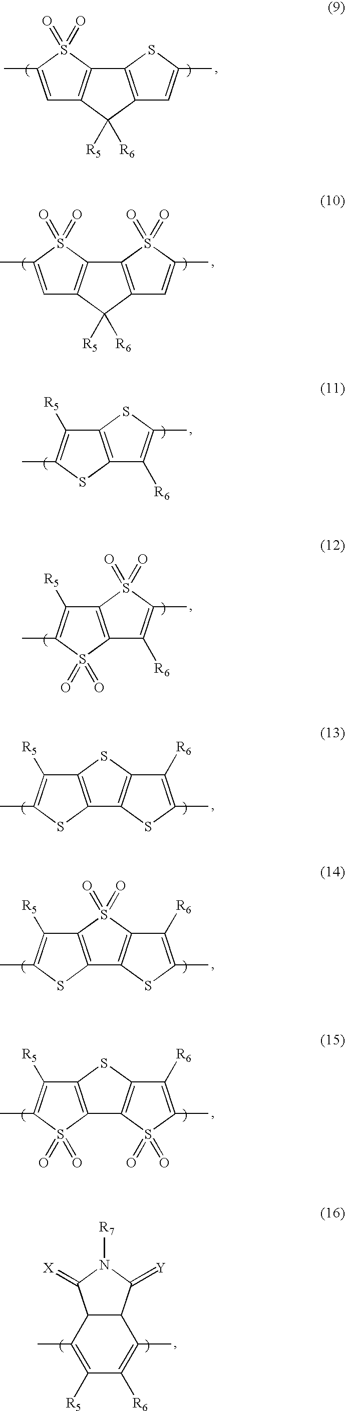

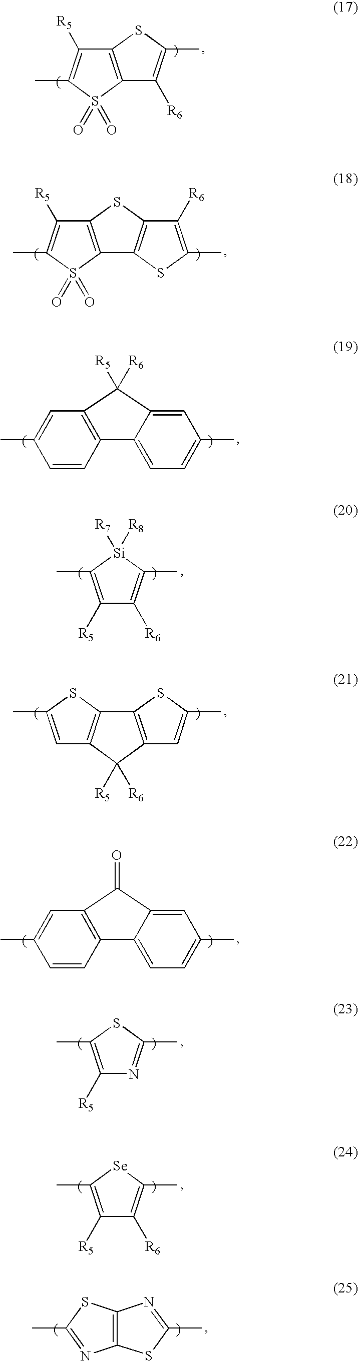

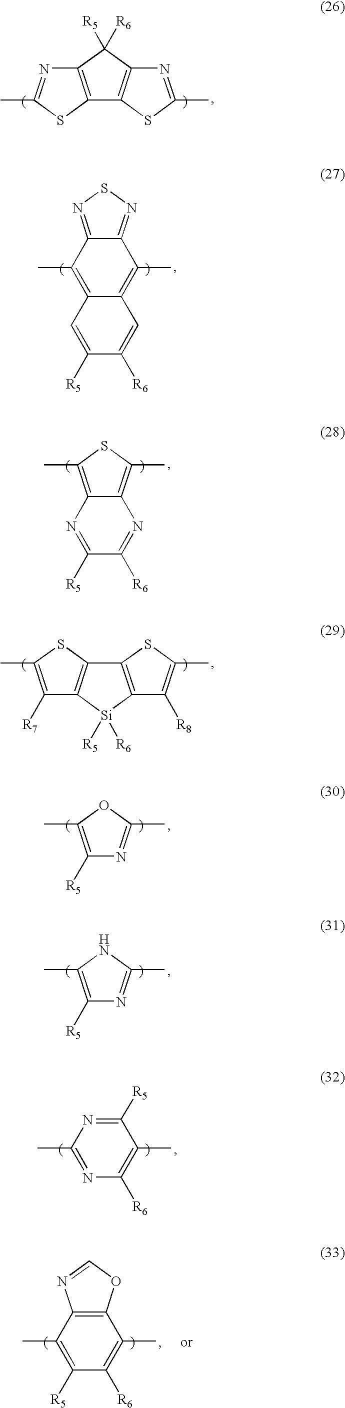

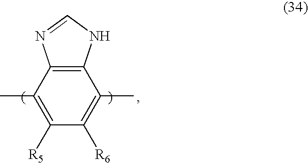

In the above formulas, each of X and Y, independently, is CH₂, O, or S; each of R₅ and R₆, independently, is H, C₁-C₂₀ alkyl, C₁C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl. In some embodiments, the second comonomer repeat unit includes a benzothiadiazole moiety of formula (2), in which each of R₅ and R₆ is H.

The second comonomer repeat unit can include at least three thiophene moieties. In some embodiments, at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl. In certain embodiments, the second comonomer repeat unit includes five thiophene moieties.

The polymer can further include a third comonomer repeat unit that contains a thiophene moiety or a fluorene moiety. In some embodiments, the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

In some embodiments, the polymer can be formed by any combination of the first, second, and third comonomer repeat units. In certain embodiments, the polymer can be a homopolymer containing any of the first, second, and third comonomer repeat units.

In some embodiments, the polymer can be

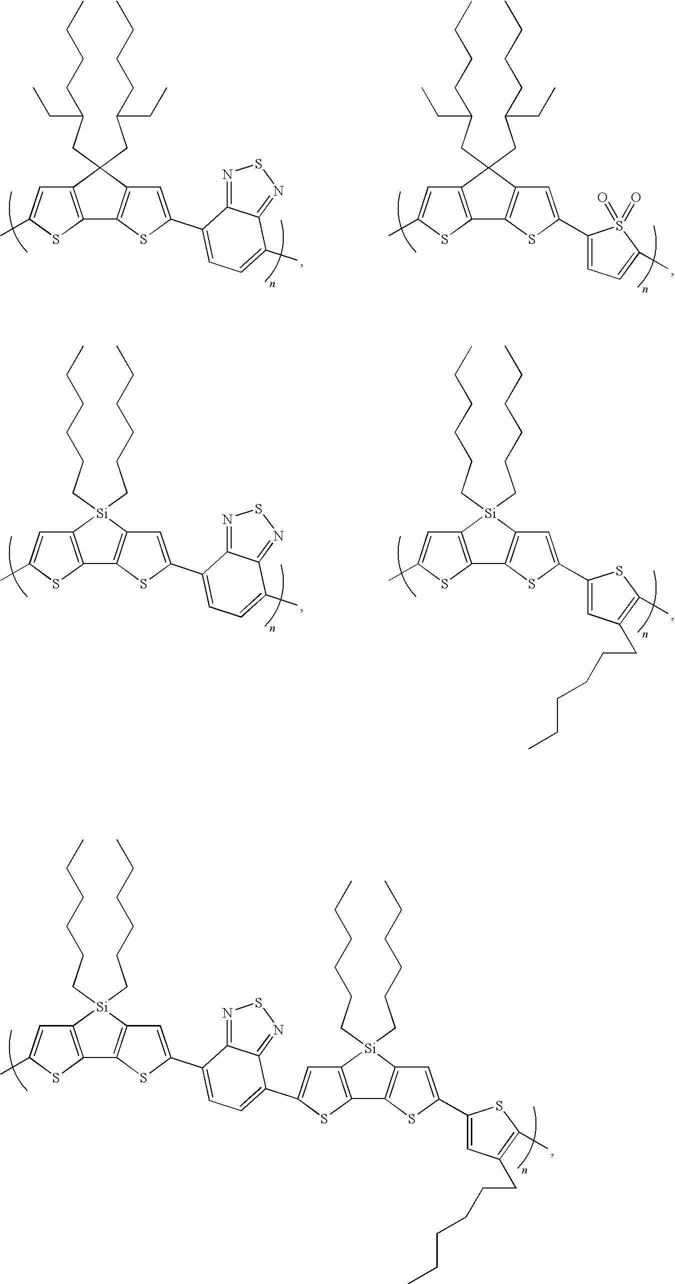

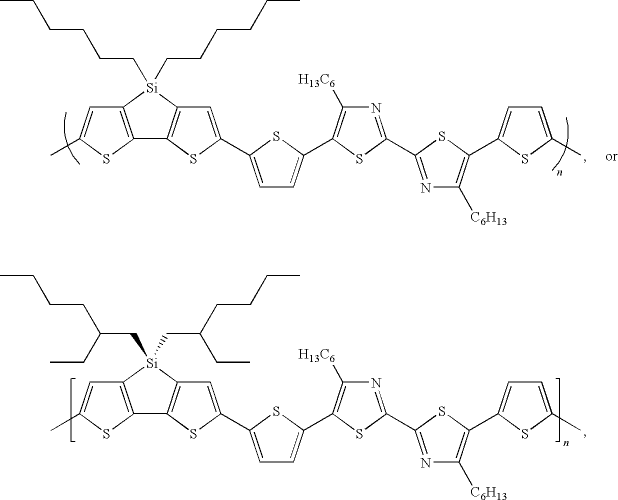

in which n can be an integer greater than 1.

The monomers for preparing the polymers mentioned herein may contain a non-aromatic double bond and one or more asymmetric centers. Thus, they can occur as racemates and racemic mixtures, single enantiomers, individual diastereomers, diastereomeric mixtures, and cis- or trans-isomeric forms. All such isomeric forms are contemplated.

The polymers described above can be prepared by methods known in the art, such as those described in commonly owned co-pending U.S. application Ser. No 11/601,374, the contents of which are hereby incorporated by reference. For example, a copolymer can be prepared by a cross-coupling reaction between one or more comonomers containing two alkylstannyl groups and one or more comonomers containing two halo groups in the presence of a transition metal catalyst. As another example, a copolymer can be prepared by a cross-coupling reaction between one or more comonomers containing two borate groups and one or more comonomers containing two halo groups in the presence of a transition metal catalyst. The comonomers can be prepared by the methods described herein or by the methods know in the art, such as those described in U.S. patent application Ser. No. 11/486,536, Coppo et al., Macromolecules 2003, 36, 2705-2711 and Kurt et al., J. Heterocycl. Chem. 1970, 6, 629, the contents of which are hereby incorporated by reference.

Without wishing to be bound by theory, it is believed that an advantage of the polymers described above is that their absorption wavelengths shift toward the red and near IR regions (e.g., 650-800 nm) of the electromagnetic spectrum, which is not accessible by most other conventional polymers. When such a polymer is incorporated into a photovoltaic cell together with a conventional polymer, it enables the cell to absorb the light in this region of the spectrum, thereby increasing the current and efficiency of the cell.

In some embodiments, photoactive layer 120 has a first band gap and photoactive layer 160 has a second band gap different from the first band gap. In such embodiments, light not absorbed by one photoactive layer can be absorbed by another photoactive layer, thereby increasing the efficiency of photovoltaic cell 100.

Generally, photoactive layer 120 or 160 is sufficiently thick to be relatively efficient at absorbing photons impinging thereon to form corresponding electrons and holes, and sufficiently thin to be relatively efficient at transporting the holes and electrons. In certain embodiments, photoactive layer 120 or 160 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, photoactive layer 120 or 160 is from about 0.1 micron to about 0.2 micron thick.

Hole carrier layers 130 and 150 are generally formed of a material that, at the thickness used in photovoltaic cell 100, transport holes to electrodes 110 and 170, and substantially block the transport of electrons to electrodes 110 and 170. Examples of materials from which layers 130 and 150 can be formed include polythiophenes (e.g., doped PEDOT), polyanilines, polyvinylcarbazoles, polyphenylenes, polyphenylvinylenes, polysilanes, polythienylenevinylenes, polyisothianaphthanenes, and copolymers thereof. In some embodiments, hole carrier layers 130 and 150 can include combinations of hole carrier materials.

In general, the thickness of hole carrier layer 130 or 150 (i.e., the distance between the surface of hole carrier layer 130 in contact with first photoactive layer 120 and the surface of electrode 140 in contact with hole carrier layer 130 and the distance between the surface of hole carrier layer 150 in contact with second photoactive layer 160 and the surface of electrode 140 in contact with hole carrier layer 150) can be varied as desired. Typically, the thickness of hole carrier layer 130 or 150 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 130 or 150 is from about 0.01 micron to about 0.5 micron.

Optionally, tandem photovoltaic cell 100 can include a first hole blocking layer (not shown in FIG. 1) between photoactive layer 120 and electrode 110 and a second hole blocking layer (not shown in FIG. 1) between photoactive layer 160 and electrode 170. Each of these two hole blocking layers can generally be formed of a material that, at the thickness used in photovoltaic cell 100, transports electrons to electrode 110 or 170 and substantially blocks the transport of holes to electrode 110 or 170. Examples of materials from which the hole blocking layers can be formed include LiF, metal oxides (e.g., zinc oxide, titanium oxide), and amines (e.g., primary, secondary, or tertiary amines). Examples of amines suitable for use in a hole blocking layer have been described, for example, in commonly-owned co-pending U.S. Provisional Application Ser. No. 60/926,459, the entire contents of which are hereby incorporated by reference.

Without wishing to be bound by theory, it is believed that when photovoltaic cell 100 includes a hole blocking layer made of amines, it can facilitate the formation of ohmic contact between photoactive layer 120 and electrode 110 or between photoactive layer 160 and electrode 170, thereby reducing damage to photovoltaic cell 100 resulted from UV exposure.

Typically, each hole blocking layer is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

In general, each of electrodes 110 and 170, photoactive layers 120 and 160, hole carrier layers 130 and 150, and the optional hole blocking layers described above can be prepared by a liquid-based coating process, such as one of the processes described above.

In some embodiments, when a layer (e.g., one of layers 110-130 and 150-170) includes inorganic semiconductor nanoparticles, the liquid-based coating process can be carried out by (1) mixing the nanoparticles with a solvent (e.g., an aqueous solvent or an anhydrous alcohol) to form a dispersion, (2) coating the dispersion onto a substrate, and (3) drying the coated dispersion. In certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a photoactive layer, (3) hydrolyzing the dispersion to form an inorganic semiconductor nanoparticles layer (e.g., a titanium oxide nanoparticles layer), and (4) drying the inorganic semiconductor material layer. In certain embodiments, the liquid-based coating process can be carried out by a sol-gel process.

In general, the liquid-based coating process used to prepare a layer containing an organic semiconductor material can be the same as or different from that used to prepare a layer containing an inorganic semiconductor material. In some embodiments, when a layer (e.g., one of layers 110-130 and 150-170) includes an organic semiconductor material, the liquid-based coating process can be carried out by mixing the organic semiconductor material with a solvent (e.g., an organic solvent) to form a solution or a dispersion, coating the solution or dispersion on a substrate, and drying the coated solution or dispersion. For example, an organic photoactive layer can be prepared by mixing an electron donor material (e.g., P3HT) and an electron acceptor material (e.g., C61-PCBM) in a suitable solvent (e.g., xylene) to form a dispersion, coating the dispersion onto a substrate, and drying the coated dispersion.

The liquid-based coating process mentioned herein can be carried out at an elevated temperature (e.g., at least about 50° C., at least about 100° C., at least about 200° C., or at least about 300° C.). The temperature can be adjusted depending on various factors, such as the coating process and the coating composition used. For example, when preparing a layer containing inorganic nanoparticles, the nanoparticles can be sintered at a high temperature (e.g., at least about 300° C.) to form interconnected nanoparticles. On the other hand, when a polymeric linking agent (e.g., poly(n-butyl titanate)) is added to the inorganic nanoparticles, the sintering process can be carried out at a lower temperature (e.g., below about 300° C.).

In general, the manner in which tandem photovoltaic cell 100 is manufactured can vary as desired. In some embodiments, tandem photovoltaic cell 100 can be manufactured by producing each layer from the bottom to the top in a sequential order. In some embodiments, tandem photovoltaic cell 100 can be manufactured by (1) disposing electrode 140 between hole carrier layers 130 and 150 to form a first intermediate article, (2) disposing the first intermediate article between photoactive layers 120 and 160 to form a second intermediate article, and (3) disposing the second intermediate article between electrodes 110 and 170. In some embodiments, tandem photovoltaic cell 100 can be manufactured by forming photoactive layer 120 on electrode 110 (e.g., by disposing a liquid-based coating composition on electrode 110) to provide an intermediate article and forming additional components (e.g., electrodes 140 and 170, hole carrier layers 130 and 150, and photoactive layer 160) to the intermediate article. For example, hole carrier layer 130 and electrode 140 can be sequentially applied onto the intermediate article to form a second intermediate article. Hole carrier layer 150, photoactive layer 160, and electrode 170 can then be sequentially applied onto the second intermediate article to form tandem photovoltaic cell 100. In some embodiments, at least a portion of tandem photovoltaic cell 100 (e.g., the entire tandem photovoltaic cell 100) is manufactured via a roll-to-roll process. In general, the electrical connections between the electrodes and the electrical connections between the electrodes and an external load can be prepared by methods well known in the art.

While certain embodiments have been disclosed, other embodiments are also possible.

In some embodiments, photovoltaic cell 100 includes cathodes as top and bottom electrodes, and an anode as a middle electrode. In some embodiments, photovoltaic cell 100 can also include anodes as top and bottom electrodes, and a cathode as a middle electrode.

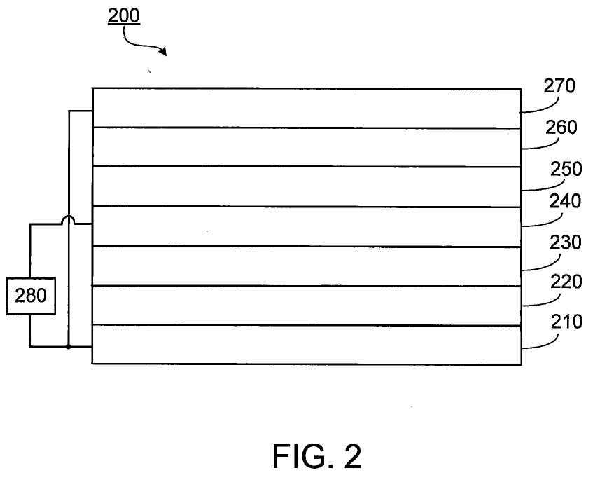

In some embodiments, a parallel tandem photovoltaic cell can include the layers shown in FIG. 1 in a different order. For example, FIG. 2 shows a parallel tandem photovoltaic cell 200 having an electrode 210, a hole carrier layer 220, a photoactive layer 230, an electrode 240, a photoactive layer 250, a hole carrier layer 260, an electrode 270, an electrical connection connecting electrodes 210 and 270, and an external load 280 electrically connected to photovoltaic cell 200 via electrodes 210, 240, and 270. Photovoltaic cell 200 can also include a hole blocking layer (not shown in FIG. 2) between electrode 240 and photoactive layer 230 and a hole blocking layer (not shown in FIG. 2) between electrode 240 and photoactive layer 250.

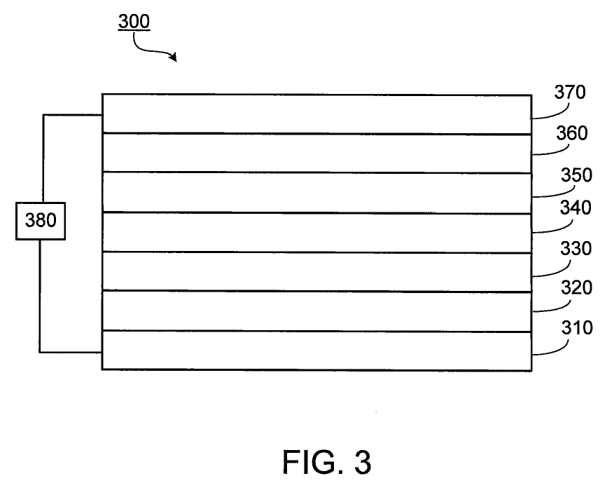

While FIG. 1 shows that photovoltaic cell 100 includes two semi-cells electrically connected in parallel, a photovoltaic cell can also includes two semi-cells electrically connected in series. For example, FIG. 3 shows a series connected tandem photovoltaic cell 300 having an electrode 310, a hole carrier layer 320, a photoactive layer 330, an electrode 340, a photoactive layer 350, a hole carrier layer 360, an electrode 370, and an external load 380 electrically connected to photovoltaic cell 300 via electrode 310 and 370. Photovoltaic cell 300 can also include a hole blocking layer (not shown in FIG. 3) between photoactive layer 330 and electrode 340, and a hole blocking layer (not shown in FIG. 3) between electrode 340 and photoactive layer 350.

While FIG. 1 shows that photovoltaic cell 100 includes two semi-cells, in some embodiments, photovoltaic cell 100 can include more than two semi-cells (e.g., 3, 4, 5, 10, 20, 50, or 100) semi-cells. In some embodiments, all of the semi-cells are electrically connected in parallel. In some embodiments, some of the semi-cells are electrically connected in series and some of the semi-cells are electrically connected in parallel.

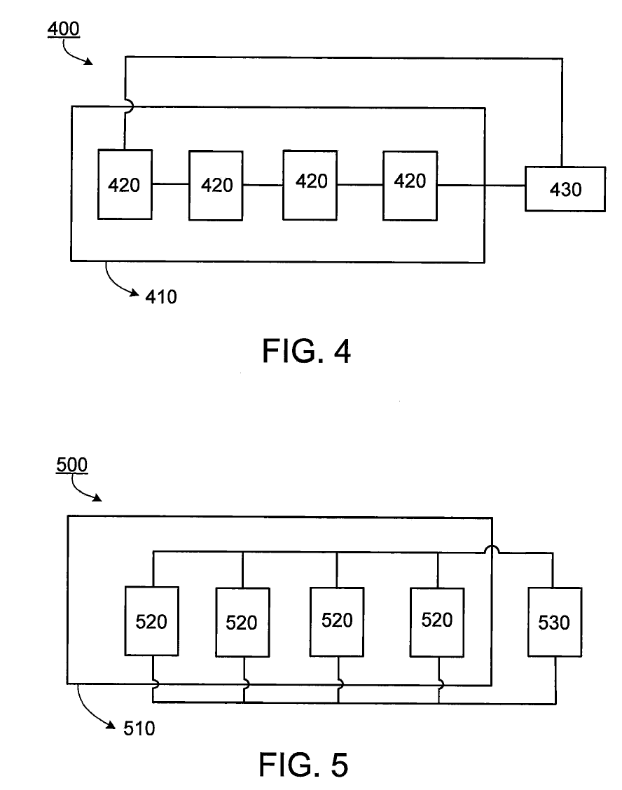

In some embodiments, multiple tandem photovoltaic cells can be electrically connected to form a photovoltaic system. As an example, FIG. 4 is a schematic of a photovoltaic system 400 having a module 410 containing tandem photovoltaic cells 420. Cells 420 are electrically connected in series, and system 400 is electrically connected to a load 430. As another example, FIG. 5 is a schematic of a photovoltaic system 500 having a module 510 that contains tandem photovoltaic cells 520. Cells 520 are electrically connected in parallel, and system 500 is electrically connected to a load 530. In some embodiments, some (e.g., all) of the photovoltaic cells in a photovoltaic system can have one or more common substrates. In certain embodiments, some tandem photovoltaic cells in a photovoltaic system are electrically connected in series, and some of the tandem photovoltaic cells in the photovoltaic system are electrically connected in parallel.

While photovoltaic cells have been described above, in some embodiments, the electrodes described herein can be used to prepare other electronic devices and systems. For example, the electrodes can be used in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

The following examples are illustrative and not intended to be limiting.

### EXAMPLE

A thin TiOₓ layer was first applied onto a PET:ITO substrate. An active layer was then prepared by blade coating a solution of P3HT:PCBM in xylene onto the TiOₓ layer at 65° C. at a rate of 60 mm/s. A hole carrier layer of PEDOT:PSS was blade coated on top of the active layer at 80° C. at a rate of 2.5 mm/s. The first semi-cell was prepared by sequential thermal evaporation of thin, semi-transparent layers of chromium (1 nm) and gold (4 nm). The second semi-cell was prepared by blade coating of PEDOT:PSS at 80° C. at a rate of 2.5 mm/s, followed by forming an active layer of P3HT:PCBM by blade coating at 25° C. at a rate of 25 mm/s and then thermal evaporation of aluminium.

The performance of the parallel tandem photovoltaic cell, as well as each of the first and second semi-cells alone, was measured under AM 1.5 illumination conditions at 25° C. by using a Steuemagel Solar Simulator and a KEITHLEY 2400 SMU detector. The performance of the first semi-cell was measured by contacting the detector with the ITO and gold electrodes, and the performance of the second semi-cell was measured by contacting the detector with the gold and aluminium electrodes. The performance of the tandem photovoltaic cell was measured by contacting the detector with the gold as the positive electrode and the ITO and aluminium together as the negative electrode.

Results showed that when two semi-cells were electrically connected in parallel, the first semi-cell (i.e., the semi-cell where the incident light enters the tandem photovoltaic cell first) exhibited much larger current (either leakage or electron injection current) than the second semi-cell. The overall current (e.g., leakage current or electron injection current) of the parallel tandem photovoltaic cell was about the sum of the current of the first semi-cell and half of the current of the second semi-cell. The parallel tandem photovoltaic cell exhibited a higher efficiency than each of the semi-cells.

Other embodiments are within the following claims.

What is claimed is:

1. A system, comprising:
a first semi-cell comprising a first electrode, a third electrode, and a first photoactive layer between the first and third electrodes; and
a second semi-cell comprising a second electrode, the third electrode, and a second photoactive layer between the second and third electrodes;
wherein the first and second semi-cells are electrically connected in parallel; the third electrode is between the first and second electrodes and comprises a first material selected from the group consisting of metals, carbon nanotubes, carbon nanorods, fullerenes, and combinations thereof; and the system is configured as a photovoltaic system.

2. The system of claim 1, wherein the third electrode further comprises a second material.

3. The system of claim 2, wherein the second material comprises a metal oxide, an electrically conductive polymer, or a combination thereof.

4. The system of claim 3, wherein the second material comprises a metal oxide selected from the group consisting of zinc oxides, titanium oxides, indium tin oxides, and tin oxides.

5. The system of claim 4, wherein the metal oxide is in the form of nanoparticles.

6. The system of claim 3, wherein the second material comprises an electrically conductive polymer selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers thereof.

7. The system of claim 1, wherein the first material comprises a metal selected from the group consisting of iron, gold, silver, copper, aluminum, nickel, palladium, platinum, titanium, and alloys thereof.

8. The system of claim 1, wherein the first material comprises metal nanoparticles or metal nanorods.

9. The system of claim 1, wherein the first material comprises a metal mesh or a metal grid.

10. The system of claim 2, wherein the third electrode comprises a first electrode layer and a second electrode layer.

11. The system of claim 10, wherein the first electrode layer comprises a first species of the second material and the second electrode layer comprises a second species of the second material.

12. The system of claim 11, wherein the first species is different from the second species.

13. The system of claim 11, wherein the first and second species each comprises an n-type semiconductor material.

14. The system of claim 11, wherein the first and second species each comprises a p-type semiconductor material.

15. The system of claim 11, wherein the third electrode further comprises an electrically conductive layer between the first and second electrode layers.

16. The system of claim 15, wherein the electrically conductive layer comprises the first material.

17. The system of claim 1, further comprising a first hole carrier layer between the first photoactive layer and the first electrode, and a second hole carrier layer between the second photoactive layer and the second electrode.

18. The system of claim 17, further comprising a first hole blocking layer between the first photoactive layer and the third electrode, and a second hole blocking layer between the second photoactive layer and the third electrode.

19. The system of claim 1, further comprising a first hole blocking layer between the first photoactive layer and the first electrode, and a second hole blocking layer between the second photoactive layer and the second electrode.

20. The system of claim 19, further comprising a first hole carrier layer between the first photoactive layer and the third electrode, and a second hole carrier layer between the second photoactive layer and the third electrode.

21. The system of claim 1, wherein the third electrode has a thickness of at least about 10 nm.

22. The system of claim 1, wherein the third electrode has a thickness of at most about 1 micron.

23. The system of claim 1, wherein the third electrode has a surface resistance of at most about 500 Ohm/square.

24. The system of claim 1, wherein the third electrode has a surface resistance of at most about 10 Ohm/square.

25. The system of claim 1, wherein the third electrode has a transmittance of at least about 60%.

26. The system of claim 1, wherein the third electrode has a transmittance of at least about 80%.

27. The system of claim 1, the photovoltaic system comprises a tandem photovoltaic cell.

28. A system, comprising:
first and second electrodes, the first and second electrodes having the same polarity during use of the system;
a third electrode between the first and second electrodes, the third electrode having a polarity opposite to the polarity of the first and second electrodes during use of the system;
a first photoactive layer between the first and third electrodes; and
a second photoactive layer between the second and third electrodes;
wherein the third electrode comprises first and second materials, the first material being selected from the group consisting of metals, carbon nanotubes, carbon nanorods, fullerenes, and combinations thereof and the second material being selected from the group consisting of metal oxides, electrically conductive polymers, and combinations thereof; and the system is configured as a photovoltaic system.

29. The system of claim 28, wherein the photovoltaic system comprises a tandem photovoltaic cell.

30. A system, comprising:
a tandem photovoltaic cell, comprising:
two semi-cells; and
a shared electrode between the two semi-cells, the shared electrode comprising first and second materials, the first material being selected from the group consisting of metals, carbon nanotubes, carbon nanorods, fullerenes, and combinations thereof and the second material being selected from the group consisting of metal oxides, electrically conductive polymers, and combinations thereof.

31. A system, comprising:
first, second, and third electrodes, the third electrode being between the first and second electrodes;
first and second photoactive layers, the first photoactive layer being between the first and third electrodes and the second photoactive layer being between the second and third electrodes; and
first and second hole carrier layers, the first hole carrier layer being between the first photoactive layer and the third electrode and the second hole carrier layer being between the second photoactive layer and third electrode;
wherein the system is configured as a photovoltaic system.

32. The system of claim 31, further comprising first and second hole blocking layers, the first hole blocking being between the first photoactive layer and the first electrode and the second hole blocking layer being between the second photoactive layer and second electrode.

33. A system, comprising:
first, second, and third electrodes, the third electrode being between the first and second electrodes;
first and second photoactive layers, the first photoactive layer being between the first and third electrodes and the second photoactive layer being between the second and third electrodes; and
first and second hole carrier layers, the first hole carrier layer being between the first photoactive layer and the first electrode and the second hole carrier layer being between the second photoactive layer and second electrode;
wherein the system is configured as a photovoltaic system.

34. The system of claim 33, further comprising first and second hole blocking layers, the first hole blocking being between the first photoactive layer and the third electrode and the second hole blocking layer being between the second photoactive layer and third electrode.
